(19) United States
(12) Patent Application Publication
(10) Pub. No.: US 2024/0253183 A1
(43) Pub. Date: Aug. 1, 2024

(54) APPARATUS AND METHOD FOR CONTROLLING SUBSTRATE POLISH EDGE UNIFORMITY

(71) Applicant: Applied Materials, Inc., Santa Clara, CA (US)

(72) Inventors: Priscilla Michelle Diep LAROSA, San Jose, CA (US); Haosheng WU, Fremont, CA (US); Jimin ZHANG, San Jose, CA (US); Taketo SEKINE, Cuppertino, CA (US); Chen-Wei CHANG, San Jose, CA (US); Jianshe TANG, San Jose, CA (US); Brian J. BROWN, Palo Alto, CA (US); Wei LU, Fremont, CA (US); Ekaterina A. MIKHAYLICHENKO, San Jose, CA (US); Huanbo ZHANG, San Jose, CA (US); Jeonghoon OH, Saratoga, CA (US); Eric LAU, Santa Clara, CA (US); Andrew NAGENGAST, Sunnyvale, CA (US); Takashi FUJIKAWA, Sunnyvale, CA (US); Thomas H. OSTERHELD, Mountain View, CA (US); Steven M. ZUNIGA, Soquel, CA (US)

(21) Appl. No.: 18/401,306

(22) Filed: Dec. 29, 2023

Related U.S. Application Data
(60) Provisional application No. 63/441,432, filed on Jan. 26, 2023.

(51) Int. Cl. B24B 57/02; B24B 37/015; B24B 53/017

(52) U.S. Cl. CPC B24B 57/02; B24B 37/015; B24B 53/017

(57) ABSTRACT

A method and apparatus for dispensing polishing fluids and onto a polishing pad within a chemical mechanical polishing (CMP) system are disclosed herein. In particular, embodiments herein relate to a CMP system with a first fluid delivery arm and a second fluid delivery arm disposed over the polishing pad to dispense fluid, such as a polishing fluid or water, and/or provide a vacuum pressure. The second fluid delivery arm is configured to dispense a fluid or vacuum pressure onto the polishing pad to effect the polishing rate at the edge of the substrate.

### RELATED APPLICATIONS

This application claims benefit of and priority to U.S. Application No. 63/441,432, filed Jan. 26, 2023, the entire contents of which are incorporated herein by reference.

### BACKGROUND

### Field

Embodiments of the present disclosure generally relate to chemical mechanical polishing (CMP) systems used in the manufacturing of semiconductor devices. In particular, embodiments herein relate to apparatus and methods for uniform material removal across a surface of a substrate during CMP processing.

### Description of the Related Art

Chemical mechanical polishing (CMP) is commonly used in the manufacturing of semiconductor devices to planarize or polish a layer of material deposited on a substrate surface. In a typical CMP process, a substrate is retained in a substrate carrier, which presses the backside of the substrate towards a rotating polishing pad in the presence of a polishing fluid. Generally, the polishing fluid comprises an aqueous solution of one or more chemical constituents and abrasive particles suspended in the aqueous solution. Material is removed across the material layer surface of the substrate in contact with the polishing pad through a combination of chemical and mechanical activity that is provided by the polishing fluid and the relative motion of the substrate and the polishing pad.

The polishing fluid is generally dispensed onto the polishing pad from a first arm towards the center of the polishing pad so that the polishing fluid migrates towards an outer edge of the polishing pad as the polishing pad rotated. The polishing fluid often accumulates near the edge of the substrate underneath the substrate carrier. The accumulation of the polishing fluid near the substrate edge results in uneven substrate material removal profiles and either increased or decreased removal rates near the edge. Even when polishing fluid is dispersed evenly under the substrate, interaction between the substrate and the retaining ring of the substrate carrier causes non-uniformities near the edge of the substrate during CMP processes.

Accordingly, there is a need in the art for articles and related methods that solve the problem described above.

### SUMMARY

Embodiments of the present disclosure generally include a method of polishing a substrate comprising: urging a substrate against a surface of a pad of a polishing system using a carrier assembly, wherein the pad has a pad radius and a central axis from which the pad radius extends; translating the carrier assembly across a surface of the pad while rotating the carrier assembly about a rotational axis; dispensing a first fluid onto the pad from a first fluid nozzle at a first temperature and a first flow rate, wherein the first fluid is delivered to the pad at a second radial distance that is measured from the central axis; and dispensing a second fluid onto the pad from a second fluid nozzle at a second flow rate and at a second temperature, wherein the second fluid is delivered to the pad at a third radial distance that is measured from the central axis, such that the third radial distance is greater than the second radial distance.

Embodiments of the present disclosure may also include an apparatus for processing a substrate, comprising: a pad disposed on a platen, wherein the pad has a pad radius and a central axis from which the pad radius extends; a carrier assembly configured to be disposed on a surface of the pad and having a carrier radius that extends from a rotational axis of the carrier assembly, wherein the rotational axis is disposed at a first radial distance from the central axis; a first fluid delivery arm having a first nozzle configured to provide a first fluid to a first point on a surface of the pad at a second radial distance from the central axis; and a second nozzle configured to provide a second fluid to a second point on the surface of the pad, the second point disposed a third radial distance from the central axis, wherein the third radial distance is greater than or equal to the first radial distance and the second radial distance.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side view of a polishing system that may be used with the methods provided herein, according to one embodiment.

FIG. 2 is a schematic plan view of the polishing system of FIG. 1A, according to one embodiment.

FIG. 3A is a schematic side view of a portion of the polishing system, of FIGS. 1 and 2.

FIG. 3B is a schematic side view of a portion of the polishing system, of FIGS. 1A and 2, according to one embodiment.

FIG. 3C is a simplified schematic plan view of a portion of the polishing system of FIGS. 3A and 3B.

FIG. 4 is a diagram illustrating a method of dispensing one or more fluids within the polishing system of FIGS. 1-3.

Appendix A includes additional information relating aspects of the disclosure provided herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to apparatus and method for improving planarization uniformity of a chemical mechanical polishing (CMP) process by controlling the delivery of polishing fluids onto a polishing pad within a CMP system and in some cases adjusting one or more physical properties or features formed within a polishing pad. In particular, some of the embodiments disclosed herein include a CMP system with a first fluid delivery arm disposed over the polishing pad to dispense a first fluid, such as polishing fluid or water, and a second fluid delivery arm disposed over the polishing pad to dispense a second fluid, such as a polishing fluid, air or water, or to provide vacuum to remove fluid disposed on the polishing pad.

The first fluid delivery arm is positioned to deliver a polishing fluid to an inner portion of the polishing pad, such that the first fluid delivery arm supplies first fluid (e.g., first polishing fluid) to polish the substrate. The second fluid delivery arm is positioned such that the second fluid delivery arm supplies one or more second fluids (e.g., second polishing fluid, aqueous chemistry, gas, etc.) and/or water, or to provide an evacuating nozzle (e.g., vacuum) over the polishing pad to remove at least a portion of a fluid disposed on the surface of the polishing pad. The first fluid delivery arm and the second fluid delivery arm are positioned to supply polishing fluids and/or water to one or more portions of the polishing pad. In some embodiments, the first fluid delivery arm supplies one or more first fluids closer to a center of the polishing pad, whereas the second fluid delivery arm supplies one or more second fluids, or creates an evacuated region closer to the outer edge of the polishing pad. The second fluid delivery arm may be configured to dispense the one or more second fluids or provide a vacuum at a position on the polishing pad radially outward of a position on the polishing pad that the one or more first fluids are dispensed from the first fluid delivery arm. In some embodiments, the second fluid delivery arm is positioned such that the one or more second fluids are dispensed, or vacuum is provided over a different portion of the polishing pad, which is in a desired position relative to an edge of the substrate while a substrate carrier urges the substrate against the polishing pad. The one or more second fluids dispensed or vacuum provided by the second fluid delivery arm interacts with the one or more first fluids dispensed by the first fluid delivery arm as the substrate and the polishing pad rotate to provide improved polishing results on the processed substrate.

As is discussed further below, the second fluid delivery arm is moveable and may move in a synchronized pattern with the substrate carrier, such that the second fluid delivery arm delivers the one or more second fluids to the polishing pad, or positions the evacuated region, at a consistent distance from the substrate carrier as the substrate carrier is moved relative to the polishing pad and platen, which supports the polishing pad. Alternatively, the second fluid delivery arm is configured to deliver the one or more second fluids to the polishing pad, or positions the evacuated region, at a desired radius of the polishing pad that coincides with a desired position on the substrate carrier and substrate. In some embodiments, the second fluid delivery arm moves to or is positioned to accommodate a change in position of the substrate carrier from a first carrier position to a second carrier position and delivers the one or more second fluids to a portion of the polishing pad, or positions the evacuated region over a portion of the polishing pad, so that the first fluid dispensed by a nozzle in the first fluid delivery arm, is altered due to the delivery of the second fluid, or removal of a portion of the first fluid by the vacuum, will intersect a desired portion of the substrate carrier as the platen rotates under the substrate carrier.

It has been found that the results of a CMP process can be controlled by changing the distribution and/or concentration of polishing fluid disposed between a substrate and the surface of the polishing pad during processing. In some embodiments, planarization uniformity is improved by changing the composition of the polishing fluids near an edge of the substrate when the substrate is at or near the edge of the polishing pad while polishing. The first fluid delivery arm is generally used to disperse provide the one or more first fluids across the polishing pad so that the dispensed fluid is disposed underneath the substrate carrier while the substrate carrier is translating across the polishing pad. The accumulation of polishing fluids between a retaining ring and the substrate during polishing can either accelerate or decelerate the polishing rate near the edge of the substrate depending upon the type of polishing fluid, the consistency of the polishing fluid, the composition of the polishing fluid, the thickness of the accumulated polishing fluid, the rate or rotation of the substrate, and the temperature of the polishing fluid.

The accumulation of polishing fluids near the edge of the substrate is able to be controlled by the delivery of fluids from both of the first fluid delivery arm and the second fluid delivery arm. As the first fluid delivery arm is supplying the one or more fluids, which will interact with the entirety of the substrate, controlling the accumulation of polishing fluid near the edge of the substrate using the fluid dispensed from the first fluid delivery arm is difficult. It has been found that the concentration and quantity of one or more polishing fluids near the edge of the substrate can be better controlled when utilizing a second fluid delivery arm that is configured alter a property of a fluid that has been dispensed on the polishing pad. The various embodiments disclosed herein will provide additional processing parameters that are used to control the interaction of the fluids that come into contact with the substrate during a polishing process. In some embodiments, the processing parameters include the ability to control the composition and/or amount of the fluid provided near or residing near a desired position on the substrate (e.g., substrate edge) without interacting with other portions of the substrate (e.g., inner or central portion of the substrate). In some embodiments disclosed herein, the edge of the substrate is defined as the outermost 10 mm of the substrate, such that the center portion of the substrate is the innermost 140 mm of the radius for a 300 mm substrate.

In embodiments in which the dispensed liquid from the second fluid delivery arm includes a polishing fluid, the amount of polishing fluid accumulated near the edge and/or other region of the substrate can be altered, such as the amount provided can be increased or the composition can be changed. In embodiments in which the fluid is dispensed by the second fluid deliver arm is water or a chemical solution (e.g., acid, base or additive), the composition of the polishing fluid accumulated near the edge and/or other region of the substrate can be decreased as the water or chemical solution may alter the polishing fluid at a position on the substrate surface, such as near the edge of the substrate. A typical polishing fluid used in a CMP process may comprise an aqueous solution of one or more chemical constituents along with one or more types of abrasive particles suspended in the aqueous solution. The increase or decrease in fluid accumulation and fluid component concentration, such as polishing fluid accumulation and the concentration of the abrasive particles and/or chemical composition of the polishing fluid, near the edge of the substrate during CMP processing can accelerate or decelerate the removal rate near the edge of the substrate. By dispensing a liquid from the second fluid delivery arm, or evacuating a region of the polishing pad, the polishing rate at the substrate edge can be controlled by controlling the delivery of one or more fluids to a desired position relative to the substrate and the polishing pad. The process of controlling the delivery of the one or more fluids, in addition to the first fluid delivered by the first delivery arm, will typically include the process of controlling the relative position of the delivery of the one or more fluids relative to a region of the substrate. In some embodiments, the amount and type of the one or more second fluids delivered to the polishing pad by the second fluid delivery arm is controlled to achieve more uniform substrate polishing results. In some embodiments, the amount of the one or more first fluids that are allowed to pass under one or more regions of a substrate during polishing, due to the removal of a portion of the first fluid by a vacuum nozzle, is controlled to achieve more uniform substrate polishing results. The amount and type of fluid varies depending upon the type of polishing being completed, such as metal, silicon, oxide or dielectric polishing processes for example. In some embodiments, a metrology tool can be disposed within the polishing system to measure the thickness of the substrate edge and determine a removal rate. The dispensing of the liquid or amount of fluid removed by a vacuum nozzle is then controllable based upon the measured removal rate by the metrology tool.

In some embodiments, the polishing pad has a polishing-control groove formed in the outer portion of the polishing pad near the edge portion of polishing pad. The polishing-control groove may be, for example, 5 millimeters (mm) to 30 mm wide. Used in conjunction with the first and second delivery arms as discussed above, the polishing-control groove further aides in the control of the fluid accumulation, fluid component concentration and also the amount of physical contact between the substrate and polishing pad near the edge of the substrate during CMP processing to effect the removal rate near the edge of the substrate. In some embodiments, the polishing-control groove may be located near the perimeter of the polishing pad. In some embodiments, a first polishing-control groove may be formed near the perimeter of the polishing pad and a second polishing control groove can be formed near the center of the polishing pad. Positioning and holding the substrate over a polishing control groove positioned at the edge and/or center of a polishing pad can help to reduce the non-uniformity of the polished substrate, particularly at the edge of the substrate.

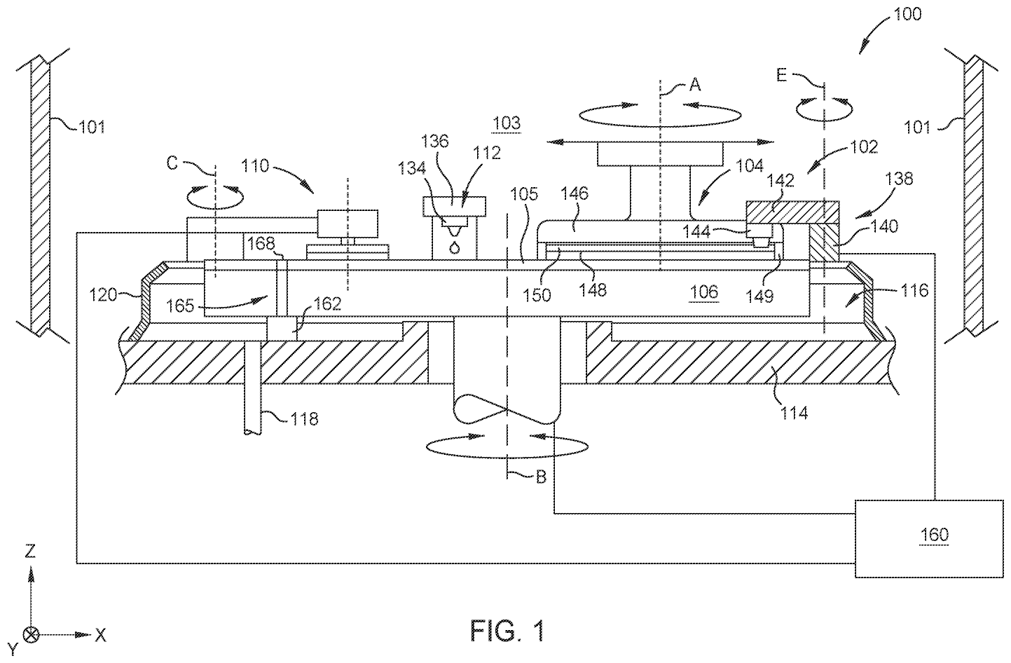

FIG. 1 is a schematic side view of a polishing system 100 that may be used with the methods provided herein, according to one embodiment. Typically, the polishing system 100 features a frame (not shown) and a plurality of panels 101, which define a substrate processing environment 103. The polishing system 100 includes a plurality of polishing stations 102 (one shown) and a plurality of substrate carrier assemblies 104 (one shown) which are disposed within the substrate processing environment 103.

As shown in FIG. 1, a polishing station 102 includes a platen 106, a polishing pad 105 mounted on the platen 106 and secured thereto, a pad conditioner assembly 110 for cleaning and/or rejuvenating the surface of the polishing pad, a first fluid delivery arm 112 for dispensing one or more first fluids onto the polishing pad 105, a second fluid delivery arm 138 for dispending one or more second fluids (e.g., a polishing fluid, chemical solution and/or a water) onto the polishing pad 105, a rotating substrate carrier assembly 104 configured to be disposed on the polishing pad 105, and a controller 160. The controller 160 is connected to each of the components (e.g., rotational motor) controlling the motion of the platen 106, the pad conditioner assembly 110, the first fluid delivery arm 112, and the second fluid delivery arm 138. Here, the platen 106 is disposed above a base plate 114 and is circumscribed by a platen shield 120 (both shown in cross-section) which collectively define a drainage basin 116. The drainage basin 116 is used to collect fluids spun radially outward from the platen 106 and to drain the fluids through a drain 118 in fluid communication therewith.

Generally, the rotating substrate carrier assembly 104 is swept back and forth across a desired region of the platen 106 while the platen 106, and thus the polishing pad 105, rotate about a platen axis B there beneath. In some configurations, the substrate carrier assembly 104 rotates and moves in a radial direction relative to the polishing pad 105 and platen 106, such that the substrate carrier assembly 104 can move along the radius of the rotating polishing pad 105. In other configurations, the substrate carrier assembly 104 rotates and moves in arcuate path relative to the center of the CMP polishing system (not shown), and thus in a non-radial direction across the polishing pad 105 and platen 106. The substrate carrier assembly 104 is rotated and moved by use of a first actuator assembly (not shown) that is positioned above the carrier head 146. The first actuator assembly is connected to the carrier head 146 of the substrate carrier assembly 104 at a shaft and the substrate carrier assembly 104 may include a track or a set of tracks (not shown) to enable movement of the carrier head 146 in either of a radial or an arcuate path across the surface of the pad. The first fluid is delivered to the polishing pad 105 using the first fluid delivery arm 112 positioned there-over and is further delivered to a polishing interface between polishing pad 105 and the substrate 148 by the rotation of the polishing pad 105 about the platen axis B. Often, the first fluid delivery arm 112 further includes a first delivery extension member 136 and a plurality of nozzles that include a first delivery nozzle 134. The plurality of nozzles are used to deliver the one or more first fluids, such as a polishing fluid and/or a relatively high pressure stream of a cleaner fluid, e.g., deionized water, to one or more positions along the surface of the polishing pad 105. One example of a first fluid can include a polishing fluid that includes, but is not limited to one or more surfactants, one or more chelating agents, one or more oxidizers, one or more corrosion inhibitors, one or more polar solvents, and deionized water. The composition may also further include one or more pH adjusting agents and/or abrasive particles. Abrasive particles which may be used in CMP compositions include, but are not limited to, alumina (Al2O3), silica (SiO2), titania (TiO2), or ceria (CeO2) particles, or any other abrasives known in the art and used in conventional CMP compositions.

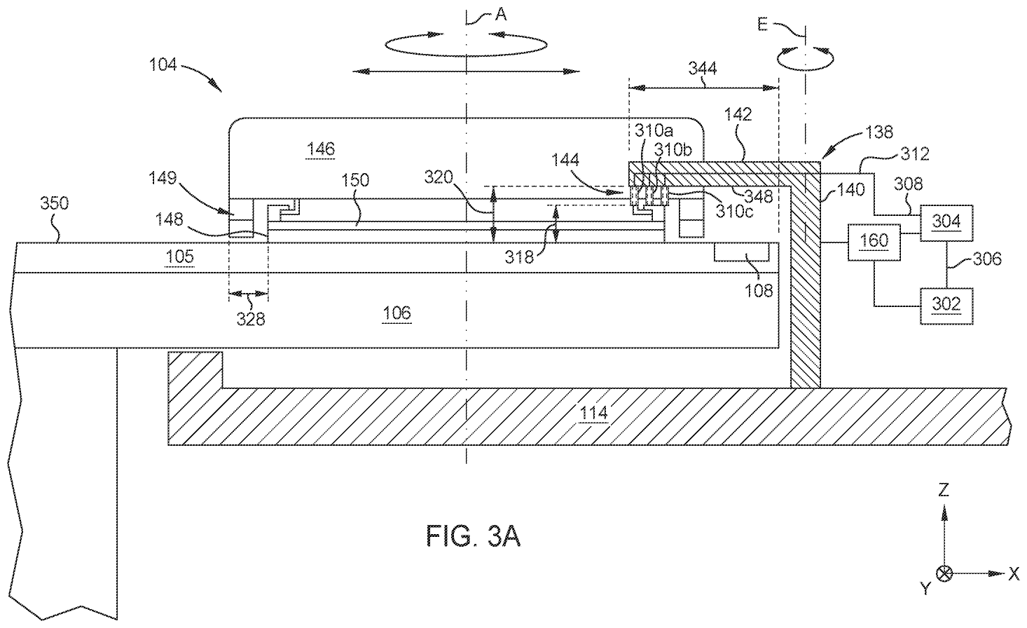

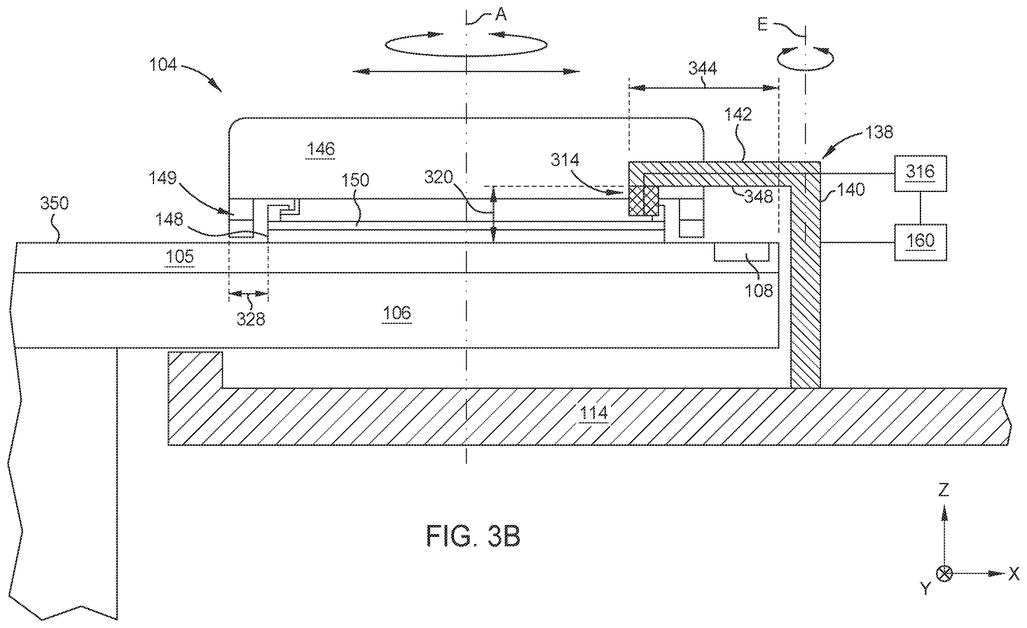

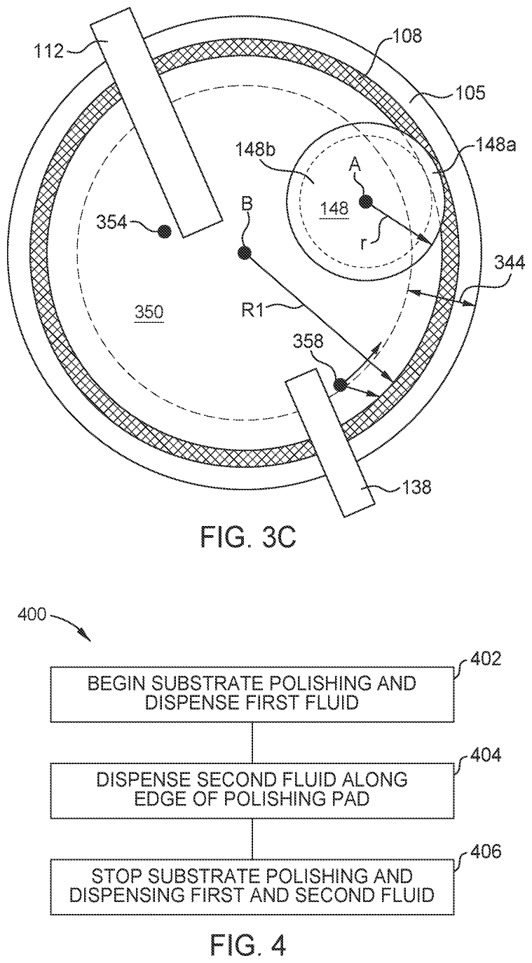

As shown in the close up cross-sectional view of the substrate carrier assembly 104 and the second fluid delivery arm 138 of FIG. 3A, the substrate carrier assembly 104 features a carrier head 146, a carrier ring assembly 149 coupled to the carrier head 146, and a flexible membrane 150 disposed radially inward of the carrier ring assembly 149 to retain and urge the substrate 148 against the polishing pad 105 during processing while the substrate carrier assembly rotates about the carrier axis A.

Referring back to FIG. 1, the second fluid delivery arm 138 includes a second actuator 140, a base plate 114, a second delivery extension member 142, and a second delivery nozzle 144. The second actuator 140 enables movement about the second delivery arm axis E, such that the second delivery extension member 142 swings about the second delivery arm axis E. The second delivery extension member 142 is coupled to the second actuator 140 at a first distal end of the second delivery extension member 142. The second delivery nozzle 144 is disposed on the opposite end of the second delivery extension member 142, such that the second delivery nozzle 144 is disposed on a second distal end of the second delivery extension member 142. The second delivery nozzle 144 is pointed downwards towards the polishing pad 105. The second delivery nozzle 144 is configured to provide one or more second fluids, such as either a polishing fluid, various chemical components, additives and/or water onto the polishing pad 105 near the outside edge of the substrate carrier assembly 104. The various chemical components can include, but are not limited to one or more surfactants, one or more chelating agents, one or more oxidizers, one or more corrosion inhibitors, one or more polar solvents, and one or more pH adjusting agents. In some embodiments, the second delivery nozzle 144 may be one or more, or a combination of a single stream dispense nozzle, spray gun nozzle, a flat fan jet spray nozzle, an atomizing nozzle or megasonic nozzle.

The metrology unit 165 includes a measurement unit 162, a window 168 disposed within the polishing pad 105. The measurement unit 162 is configured to measure the thickness of the substrate, including the substrate edge, and determine a removal rate across the substrate and the substrate edge during polishing. In some embodiments, the process of dispensing of the one or more liquids from the second fluid delivery arm is then controllable based upon the measured removal rate by the metrology tool. The measurement unit 162 may measure the thickness of the substrate edge by projecting radiation beams through the window 168 and onto the substrate 148 as the substrate passes over the window 168. The radiation beams are then reflected back to the measurement unit 162 and a thickness and/or removal rate at the edge of the substrate 148 is determined. The window 168 is an optically transparent window, such as a clear quartz window or transparent polymer.

The controller 160 is connected to each of the platen 106, the pad conditioner assembly 110, the metrology unit 165, the first fluid delivery arm 112, the second fluid delivery arm 138, and the substrate carrier assembly 104. In some aspects of the CMP polishing process, the controller 160 coordinates the rotation of the platen 106 as well as the dispensing of a first fluid, second fluid or water onto the polishing pad 105 by either of the first or second fluid delivery arms 112, 138. In some embodiments, the controller 160 uses the measurements from the metrology unit 165 to determine when one or more of the first or second fluids will be delivered, or a vacuum is applied, to the polishing pad 105. The controller 160 also controls the movement of the substrate carrier assembly 104 and may increase or decrease the amount of pressure exerted on one or more regions of the substrate by the membrane 150 within the substrate carrier assembly 104.

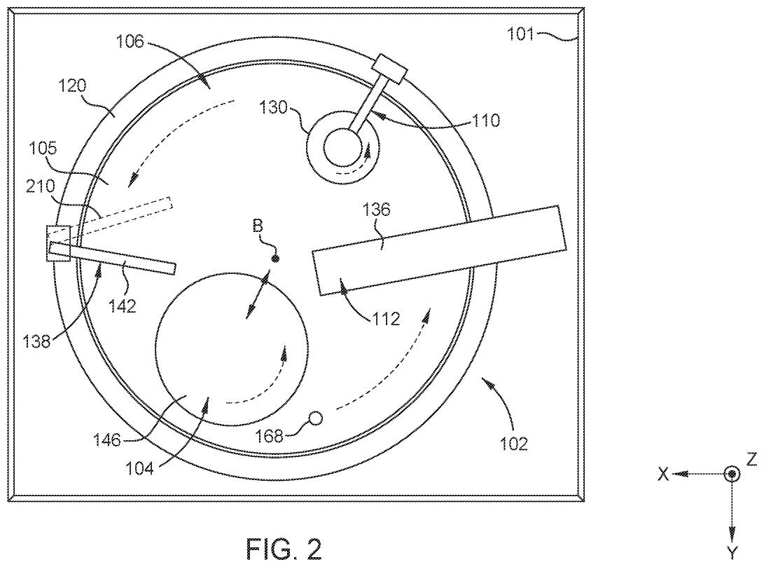

FIG. 2 is a schematic plan view of the polishing system 100 of FIG. 1, according to one embodiment. As discussed with reference to FIG. 1, each of the pad conditioner assembly 110, the first fluid delivery arm 112, the second fluid delivery arm 138, and the substrate carrier assembly 104 are disposed above the polishing pad 105. In one example, the polishing pad 105 is rotated in a counterclockwise direction by a rotation actuator (not shown) coupled to the platen 106 about the platen axis B (FIG. 1). The conditioner mounting plate 130 and the substrate carrier assembly 104 also typically rotate in a counterclockwise direction when viewed from above. In the embodiment of FIG. 2, each of the polishing pad 105, the conditioner mounting plate 130 of the pad conditioner assembly 110, and the substrate carrier assembly 104 rotate in the same direction. In some embodiments the polishing pad 105, the platen 106, the conditioner mounting plate 130, and the substrate carrier assembly 104 rotate in a clockwise direction. In some embodiments, one or more of the polishing pad 105, the platen 106, the conditioner mounting plate 130, and the substrate carrier assembly 104 rotate in a clockwise direction while the other components rotate in a counterclockwise direction.

In some embodiments, the polishing pad has a radius that is about 10 inches (254 mm) to about 30 inches (762 mm), such as about 12 inches (305 mm) to about 20 inches (508 mm), such as about 14 inches (356 mm) to about 16 inches (406 mm). In some embodiments, at least a portion of the first fluid delivery arm 112 is configured to deliver a fluid at a position that is at least 50% of the pad radius, such as over at least 60% of the pad radius, such as over at least 80% of the pad radius. In some embodiments, the first fluid delivery arm 112 is configured to deliver a fluid at a position that is at about 50% to about 90% of the pad radius, such as about 60% to about 85%. The first fluid delivery arm 112 is configured to deliver a fluid at a position that is at about 200 mm to about 360 mm inward over the polishing pad 105 from the edge of the polishing pad 105, such as about 210 mm to about 360 mm inward, such as about 225 mm to about 360 mm inward.

The first fluid delivery arm 112 is configured to dispense the first fluid across a majority of the polishing pad 105, such that the first fluid delivery arm 112 dispenses fluid radially inward of the substrate carrier assembly 104 and the first fluid delivery arm 112 is configured to provide fluid to the polishing pad such that the dispensed fluid overlaps an entirety of a radial position occupied by the substrate carrier assembly 104 over the polishing pad 105. The first fluid delivery arm 112 dispenses a first fluid, such as a polishing fluid and/or a water onto the polishing pad 105 at a first radial position. The first radial position is a position radially inward from the innermost edge of the substrate carrier assembly 104 with respect to the central axis B of the polishing pad 105.

The second fluid delivery arm 138 is also disposed over the polishing pad 105 and in some configurations is disposed on an opposite side of the platen 106 from the first fluid delivery arm 112. In one embodiment, the second fluid delivery arm 138 and the first fluid delivery arm 112 are disposed over opposite quadrants or halves (as shown in FIG. 2) of the polishing pad 105. The second fluid delivery arm 138 dispenses a second fluid, such as a polishing fluid and/or a water onto the polishing pad 105. The second fluid is dispensed onto the polishing pad 105 at a second radial position. The second radial position is a position radially inward from the outermost edge of the edge processing region 344 (FIGS. 3A-3C) with respect to the central axis B (FIG. 1) of the polishing pad 105. The second fluid is mixed with the first fluid to adjust the amount of the polishing fluids and composition of the polishing fluids near the edge of the substrate 148 when the substrate is disposed within the edge processing region 344 as the carrier head 146 and substrate 148 are translated across the polishing pad 105. In some embodiments, the mixture of the first fluid and the second fluid will either increase or reduce the amount of or concentration of one or more constituents of the first fluid across a portion of the substrate 148. In one example, the one or more constituents of the first fluid that may be adjusted by the addition of the second fluid includes the amount of and/or concentration of abrasive particles (e.g., silica-based abrasive, ceria-based abrasive, and alumina-based abrasive), water or other chemical solutions (e.g., acids, bases, inhibitors, etc.) across a portion of the substrate 148, such as the edge of the substrate 148.

The second fluid delivery arm 138 is moveable about a second delivery axis E (FIG. 1). The second fluid delivery arm 138 rotates about the second delivery axis E to change the position of the second delivery nozzle 144 over the polishing pad 105. The second fluid delivery arm 138 can be moved to and from a first position and a second position. As the substrate carrier assembly 104 moves across the polishing pad, the movement of the second fluid delivery arm 138 may be synchronized with the movement of the substrate carrier assembly 104 to keep a similar radial entry point for the second fluid along the outer circumference of the substrate carrier assembly 104. Alternatively, the second fluid delivery arm 138 is moveable relative to the surface of the polishing pad to allow for the radial entry point along the outer circumference of the substrate carrier assembly 104 to be adjustable throughout the process. In some embodiments, it is envisioned that the second fluid delivery arm 138 may have the ability to be rotated to one or more angles about the second delivery axis E, such that the second fluid delivery arm 138 can rotate between about 5 and about 180 degrees about the second delivery axis E.

FIG. 3A is a schematic side view of a portion of the polishing system 100, of FIGS. 1 and 2. FIG. 3A more specifically illustrates a side close up view of the substrate carrier assembly 104 and the second fluid delivery arm 138. The carrier head 146, the carrier ring assembly 149, the flexible membrane 150, the polishing pad 105, the platen 106, and the substrate 148 are described above. The substrate 148 is shown pressed against the polishing pad 105 by the flexible membrane 150. The flexible membrane 150 typically applies an adjustable amount of pressure across different concentric regions of the substrate 148 during polishing to improve the planarization of the surface of the substrate. The flexible membrane 150 is coupled to the substrate carrier assembly by membrane clamps (not shown).

In some embodiments, a temperature control unit 304 and a fluid source 302 are fluidly connected to the second fluid delivery arm 138. The temperature control unit 304 and fluid source 302 are connected to and controlled by the controller 160. The fluid source 302 supplies one or more second fluids to the second fluid delivery arm 138 to be dispensed onto the polishing pad 105. The fluid source 302 includes one or more fluid sources that are configured to provide the one or more second fluids, such as a polishing fluid, chemical solution and/or a water. The sources of the one or more second fluids provided from the fluid source 302 are each configured to provide their respective fluids at a desired flow rate and pressure. The polishing fluid source may provide one or more fluids that include a chemical solution (e.g., acid, base, inhibitor, etc.) and/or slurry containing solution (e.g., abrasive particle (e.g., silica, ceria, or alumina based abrasives) containing solution) used for substrate polishing. The second fluid may also include a polishing rate promoter such as H₂O₂. The water source can be a deionized water source. The fluid may also be a polishing rate inhibitor, for example benzotriazole (BTA). The fluid source may also be any typical post CMP cleaning chemical, for example, PlanarClean® and or PL6502. The fluid source 302 may include a pump or a plurality of pumps (one for each fluid).

The fluid source 302 is fluidly connected to the temperature control unit 304 by a first conduit 306. In some embodiments, the temperature control unit 304 may be integrated into the fluid source 302 and the first conduit 306 is removed. The temperature control unit 304 controls the temperature of the fluids being delivered to the second fluid delivery arm 138 and the second delivery nozzle 144 through the second conduit 308. The temperature control unit 304 may include resistive heating elements therein for heating of the fluids disposed therein. The temperature control unit 304 may also include cooling channels disposed therein for cooling the fluids or for cooling the heating elements. The temperature control unit 304 may heat or cool the fluids to temperatures suitable to enhance or inhibit the CMP polishing process. It is believed that by controlling the temperature of the fluids supplied to a first region (e.g., edge region) of a substrate during a polishing process, along with the other CMP process control variables discussed herein (e.g., amount of a fluid, concentration of fluid components, applied pressure, etc.), the chemical activity and/or interaction of the abrasive particles with the surface of the substrate can be adjusted to adjust the removal rate in the first region of the substrate versus other regions of the substrate. In one example, the temperature of the one or more second fluids supplied to an edge region of a polishing pad, and thus a portion of the substrate that is disposed in the edge region during a portion of a polishing process, is controlled to a temperature that is less than the temperature of the first fluid and polishing pad surface during a polishing process to reduce the chemical activity of the combined fluids that contact the edge region, and also in some cases alter the properties of the polishing pad material in the edge region. The temperature control unit 304 is disposed external from the second fluid delivery arm 138 to reduce the volume occupied by the second fluid delivery arm 138 and reduce the impact of the heating or cooling on the volume surrounding the second fluid delivery arm 138.

The second delivery nozzle 144 may comprise a plurality of nozzles, such as a first nozzle 310a, a second nozzle 310b, and a third nozzle 310c. The first, second, and third nozzles 310a, 310b, 310c are disposed along a bottom surface 348 of the second delivery extension member 142, such as a bottom surface of the second delivery extension member 142. The first, second, and third nozzles 310a, 310b, 310c may be angled to project fluid delivered through the first, second, and third nozzles 310a, 310b, 310c in a direction other than a vertical direction (Z-direction) that is perpendicular to the top surface 350 of the polishing pad 105. For example, the nozzle or nozzles may be positioned from 25 mm to 75 mm from the edge of polishing pad 105 and at an angle with regards to the top surface 350 of the polishing pad 105 to be directed toward the pad edge and avoid spraying fluid towards the center region of the pad 105 during processing. Although shown as disposed along a plurality of radial positions in FIG. 3A, the plurality of nozzles could also be disposed at positions with the same radial distance along the second delivery extension member 142 from the second delivery axis E, such that each of the first, second, and third nozzles 310a, 310b, 310c project fluid onto a similar radial position of the polishing pad 105. Although three nozzles are depicted as the second delivery nozzle 144 herein, it is envisioned that other quantities of nozzles may also be utilized, such as one nozzle, two nozzles, four nozzles, five nozzles, or six nozzles, so that one or more different fluids can be provided to the surface of the polishing pad 105.

The second delivery nozzle 144 may be one or more of any number of nozzle types including, but not limited to, a single stream dispense nozzle, spray gun jet nozzle, a flat fan jet spray nozzle, an atomizing nozzle or megasonic nozzle. In one embodiment, the second delivery nozzle 144 includes a dispense nozzle that has a dispense hole size between 0.5 mm to 5.0 mm that is able to achieve a flow rate of the second fluid of up to 1 liter per minute. In one embodiment, where on one or more spray gun jet nozzles are used, the fluid used is a deionized water and a nitrogen mixture where the deionized water is delivered at a flow rate of between 0.1 and 1 liters per minute and the nitrogen is delivered at a flow rate of between 10 and 300 slm. In some cases, a cleaning chemical, for example PlanarClean® and/or PL6502 is provided from a spray gun jet nozzle. The second fluid can be delivered at a temperature of between 0° C. and 95° C., such as between 1° C. and 90° C., or between 18° C. and 60° C. In one embodiment, where one or more flat fan-jet spray nozzles are used to project the fluid in a flat fan spray pattern, the spray angle of the flat fan is between 25 degrees and 180 degrees. In one embodiment, where on one or more atomizing nozzles are used, the fluid used is a deionized water and a nitrogen mixture.

In one embodiment, the fluid provided from the second delivery arm includes the delivery of a fluid from a megasonic nozzle. The megasonic nozzle includes one or more elements such as a megasonic actuator configured to alternatively apply megasonic energy in the form of waves within the provided second fluid in an alternating fashion according to a sinusoidal or other pattern to generate a megasonic actuated fluid. The second fluid can be delivered from the first fluid source 302 that is adapted to deliver deionized water and/or a cleaning solution (i.e., acid or base solution) at a rate up to 5 liters a minute and at a temperature of between 20 and 60 degrees Celsius. The megasonic nozzle may be configured to alternatively apply megasonic energy in a sinusoidal pattern at a rate of between about 100 kHz to 5 MHz, such as 950 kHz to generate the megasonic actuated fluid that is provided to the top surface 350 of the polishing pad 105. The megasonic nozzle may be configured to deliver megasonic energy at multiple frequencies, such as delivering at least two differing frequencies. It is believed that the delivery of megasonic energy to the fluids in contact with and/or residing on the surface of the polishing pad can be useful to remove the abrasive particles bonded to or residing on the surface of the polishing pad. The delivery of the megasonic energy can thus be used to alter the composition of the fluids positioned at the surface of the polishing pad (e.g., abrasive particle amount). In some CMP process sequences, the one or more second fluids may include, a cleaning chemistry, such as for example PlanarClean® and/or PL6502, that is used before, during or after a polishing process as a rinsing agent to remove the abrasive particles embedded within, bonded to or residing on the surface of the polishing pad.

The separation distance 318 between the bottom of the first, second and third nozzles 310a, 310b, 310c and the top surface 350 of the polishing pad 105 is about 5 mm to about 120 mm, such as about 10 mm to about 100 mm, such as about 10 mm to about 50 mm. The separation distance 320 between the bottom surface 348 of the second delivery extension member 142 and the top surface 350 of the polishing pad 105 is about 10 mm to about 160 mm, such as about 10 mm to about 150 mm, such as about 10 mm to about 100 mm, such as about 10 mm to about 50 mm. The separation distance 320 is greater than about 10 mm to avoid the fluid meniscus on the pad from contacting the second delivery extension member 142.

In one example, each of the first, second, and third nozzles 310a, 310b, 310c are configured to deliver different types of second fluids that each have different compositions. In another example, the first, second, and third nozzles 310a, 310b, 310c are configured to dispense both a first fluid composition and a second fluid composition at the same time or sequentially in time, such as a polishing fluid, a chemical solution and water. In one example, the first nozzle 310a is configured to dispense a polishing fluid, while the second and third nozzles 310b, 310c are configured to dispense water. In one example, the first nozzle 310a is configured to dispense a polishing fluid, while the second and third nozzles 310b, 310c are configured to dispense water that is provided at a different temperature and/or flow rate from each nozzle. In one example, the first nozzle 310a is configured to dispense water, while the second and third nozzles 310b, 310c are configured to dispense a polishing fluid. In one example, the first nozzle 310a is configured to dispense water, while the second and third nozzles 310b, 310c are configured to dispense a different polishing fluid at the same or a different temperature and/or flow rate from each nozzle. In some embodiments, there may be multiple types of polishing fluids and each of the polishing fluids are dispensed from a different nozzle at a desired temperature and flow rate.

It is possible to dispense water, a chemical solution and a polishing fluid simultaneously or separately. In one example, while a water is dispensed from a first nozzle 310a, the second and third nozzles 310b, 310c dispense polishing fluid simultaneously. In one example, the polishing fluid is dispensed from the first nozzle 310a and the second and third nozzles 310b, 310c dispense a water simultaneously. Alternatively, the polishing fluid and the water would be dispensed at separate times. In yet another example, the water and the polishing fluid are mixed before reaching the first, second, and third nozzles 310a, 310b, 310c to alter the concentration of the polishing fluid before being dispensed onto the polishing pad 105. In embodiments in which the water and polishing fluid are pre-mixed, the water and polishing fluid may be mixed in any of the fluid source 302, the temperature control unit 304, or within the conduits 306, 308, 312.

The second delivery nozzle 144 delivers fluid to the top surface 350 of the polishing pad 105 at an edge processing region 344 that is disposed a distance from the center of the polishing pad 105 to the perimeter of the polishing pad 105. The edge processing region 344 in some embodiments may be configured to be anywhere along the radius of the polishing pad 105, but in other embodiments is disposed between the carrier axis A and the outer edge of the substrate carrier assembly 104. In one embodiment, edge processing region 344 includes polishing control groove 108.

In some embodiments, by controlling the timing, flow rate and/or pressure of the fluid provided to the surface of the polishing pad the polishing rate within a region of the substrate can be further altered and controlled. It has been found in some CMP processes that by positioning the delivery of the second fluid to a desired region (e.g., edge polishing region 344) of the polishing pad and then adjusting the timing and the duration of the delivery of the second fluid the polishing rate at the edge of the substrate can be altered. For example, the flow of the second fluid can be pulsed on and off for desired durations during processing. In some embodiments, the flow of the second fluid does not have to be continuous during the CMP polishing. In one example, the delivery of the second fluid can be controlled based on specific events within the CMP polishing process, such as when a certain layer of material on a substrate is exposed during a CMP polish process, or controlled based on the in-situ metrology sensor feedback. In some embodiments, the flow of the second fluid can be pulsed, for example, on for 1 second and off for 1 second. The timing of the pulses and the on/off time ratio can be adjusted.

Referring to FIGS. 3A and 3C, in one embodiment, the polishing pad 105 has at least one polishing control groove 108 formed in the polishing surface 350. Each polishing control groove 108 is a recessed area of the polishing pad 105. Each polishing control groove 108 can be an annular groove, e.g., circular, and can be concentric with the axis of rotation B of the platen 106. Each polishing control groove 108 provides an area within edge processing region 344 of the polishing pad 105 that does not contribute to polishing.

The walls of the polishing control groove 108 are perpendicular to the polishing surface 350. The bottom surface of the polishing control groove 108 is parallel with the polishing surface 350, although in some implementations the bottom surface of the polishing control groove 108 can be angled relative to the polishing surface 350. The bottom of the polishing control groove 108 can have a rectangular or a U-shaped cross-section. The polishing control groove 108 can be 10 to 80 mils, e.g., 10 to 60 mils, deep.

In some implementations, the pad 105 includes a polishing control groove 108 located near the outer edge of the polishing pad 105, e.g., within 15%, e.g., with 10% (by radius) of the outer edge. For example, the groove 108 can be located at a radial distance R1 of fourteen inches from the center of a platen having a thirty inch diameter. The polishing control groove 108 is sufficiently wide that the by positioning a section of the substrate 148 over the groove, the polishing rate of that section will be materially reduced obtaining a more uniformly polished substrate. In particular, for edge-correction, the groove 108 is sufficiently wide that an annular band at the edge of the substrate, e.g., a band at least 3 mm wide, e.g., a band 3-15 mm wide, e.g., a band 3-10 mm wide, will have a reduced polishing rate. The polishing control groove 108 can have a width of three to fifty, e.g., five to fifty, e.g., three to ten, e.g., ten to twenty, millimeters.

FIG. 3B is a schematic side view of one embodiment of a portion of the polishing system 100, shown in FIG. 3A. FIG. 3B more specifically illustrates a side close up view of the substrate carrier assembly 104 and second fluid deliver arm 138 as shown in FIG. 3A, but FIG. 3B shows vacuum nozzle 314 attached to the end of second fluid delivery arm 138 in place of or in addition to one or more of the fluid delivery nozzles 310a-310c. Vacuum source 316 is connected to the vacuum nozzle 314 via second fluid deliver arm 138 to provide vacuum along the edge processing region 344 to remove and control the volume of slurry disposed along at the edge of the substrate during processing. The reduced volume of slurry within the edge processing region 344 (FIGS. 3A-3C) can be used to reduce the polishing rate of the portions of the substrate when portions of the substrate are disposed within the edge processing region 344. Therefore, the adjustment of the amount of slurry positioned within the edge processing region 344 is used to provide a more uniform polishing result across the substrate due to the reduction of typically high polishing rate created at the edge of the substrate. The suction flow rate and/or vacuum pressure created by the vacuum source 316 is controlled by use of the controller 160. In some embodiments, the vacuum nozzle 314 is positioned between 1 and 5 mm above the top surface of the substrate. In one embodiment, the vacuum nozzle 314 is provided together with the fluid delivery nozzles 310a-310c. In one embodiment, vacuum nozzle 314 comprises multiple vacuum nozzles such as between 2 and 6 vacuum nozzles. In one embodiment, polishing control groove 108 is positioned in the edge processing region 344 of the polishing pad 105 and vacuum nozzle 314 is positioned to remove fluid from the polishing control groove 108 during processing.

FIG. 3C is a simplified schematic plan view of a portion of the polishing system 100 of FIG. 3A. The polishing pad 105 is shown and is simplified by not showing the pad conditioner assembly 110 (FIG. 2). The polishing pad 105 shows optional polishing control groove 108 within the edge processing region 344. The first fluid delivery arm 112 dispenses fluid to a first point 354 on the polishing pad 105 so that the first fluid provided from the first fluid delivery arm 112 covers a center portion of polishing pad 105 and across the edge processing region 344 of the polishing pad 105 as the pad rotates. As discussed above, the second fluid delivery arm 138 dispenses one or more second fluids to, and/or removes material from, a second point 358 located near the inner edge of the edge processing region 344 of the polishing pad. As shown by the arrows directed from second point 358, the fluid dispensed from the second fluid deliver arm is directed towards the edge processing region 344 to adjust the properties of the fluid(s) positioned within the edge processing region 344. During processing, when the substrate 148 is moved to a position where the substrate edge portion 148a is positioned within the edge processing region 344, the polishing rate of the substrate edge portion 148a is reduced as compared to the polishing rate of the substrate center portion 148b, providing improved polishing uniformity across the substrate.

In one embodiment, the nozzles described above as associated with delivering a fluid or vacuum from the second fluid delivery arm 138 are not integrated on to the second fluid delivery arm 138, but are instead integrated on to the first fluid delivery arm 112 to achieve the same results.

FIG. 4 is a diagram illustrating a method 400 of dispensing polishing fluid from the polishing system 100 of FIGS. 1-3. The method 400 includes a first operation 402, a second operation 404, and a third operation 406. Although depicted in a sequential order herein, the operations within the method 400 may be performed in alternative orders, at the same time and/or additional operations may be included.

The first operation 402 includes beginning to polish a substrate, such as the substrate 148 and dispensing a first fluid from a first fluid delivery arm, such as the first fluid delivery arm 112 disclosed in FIGS. 1 and 2. The first fluid is provided at a first flow rate and at a first temperature to the surface of the polishing pad. The substrate is held by a substrate carrier assembly 104 and pressed into a polishing pad, such as the polishing pad 105 disclosed herein. In this example, the polishing pad is rotated in a counterclockwise direction. The substrate carrier assembly 104 may also rotate in a counterclockwise direction while oscillating along the radius of the polishing pad. The first fluid is dispensed from one or more nozzles along the first fluid delivery arm at a radius of the polishing pad, which is typically in the inner 50% of the radius of the polishing pad.

The first fluid is a polishing fluid for polishing the substrate. The polishing fluid includes a slurry and/or chemical solution containing mixture, which may include particles suspended therein to aid in polishing the substrate. The first fluid is delivered within the inner half of the radius of the polishing pad and flows along a first fluid path. In some embodiments, the first fluid is dispensed onto a location of the polishing pad, which is radially inward of the substrate carrier assembly at one or more instants in time with respect to the central axis B of the polishing pad. In some embodiments, the first fluid is delivered at a position so that the first fluid interacts with the entirety of the substrate surface as the first fluid moves outward along the rotating polishing pad. The first fluid moves outward along the polishing pad due to the rotation of the polishing pad and centrifugal forces imparted on the first fluid by the pad rotation. As the fluid moves outward along the polishing pad, the first fluid may be said to be traveling downstream, such that the first fluid is delivered at an upstream position and flows downstream and radially outward from the center of the polishing pad and towards the edge of the polishing pad.

The substrate carrier assembly holds the substrate thereunder and includes a substrate retaining ring thereunder. In some processes, the substrate retaining ring assists in keeping the substrate from sliding out from underneath the substrate carrier assembly. The substrate retaining ring therefore sometimes contacts the edge of the substrate and can cause non-uniform removal rates during the polishing process along the edge of the substrate. A buildup of the first fluid at one or more regions of the substrate surface and the substrate retaining ring may occur. The buildup of the first fluid also impacts the removal rate at the one or more regions of the substrate surface, such as near the edge of the substrate. The buildup of the polishing fluid at different regions of the substrate surface may cause either an increase or a decrease in the removal rate near the edge of the substrate. In one exemplary embodiment, a decrease in removal rate may be caused by the creation of a barrier layer between the affected substrate region (e.g., substrate edge) and the polishing pad. In yet another exemplary embodiment, the buildup of polishing fluid may increase the removal rate by exposing the substrate to a larger quantity of polishing chemicals. The inverse may also be true in that a reduction in the buildup of the polishing fluid near the edge of the substrate may either increase the removal rate or decrease the removal rate depending upon the application and the polishing fluid utilized. Therefore, a second fluid, such as deionized water or additional polishing fluid, may be dispensed onto the polishing pad and configured to interact with the first fluid near the edge of the substrate. The second fluid may alter the composition of fluids provided to the edge of the substrate and/or either thin or thicken the polishing fluid buildup near the edge of the substrate.

During processing, the carrier assembly is translated across a surface of the pad while rotating the carrier assembly about the carrier axis. Translating the carrier assembly across the surface of the pad causes a first radial distance measured from the central axis to the rotational axis to vary between a first radial value and a second radial value as the carrier assembly is translated across the surface of the pad.

A pad conditioner assembly, such as the pad conditioner assembly 110, may be used during the first operation 402 to clean or rejuvenate the polishing pad. The pad conditioner assembly rotates in a counterclockwise direction along with the substrate carrier assembly and the polishing pad. The pad conditioner assembly is disposed over the polishing pad and physically contacts the polishing pad as the pad conditioner assembly moves across the polishing pad.

The second operation 404 is generally performed subsequent the first operation 402, but in some embodiments may be performed first or simultaneously with the first operation 402. The second operation 404 includes dispensing one or more second fluids from a second fluid delivery arm, such as the second fluid delivery arm 138. The one or more second fluids are provided at a second flow rate and at a second temperature to the surface of the polishing pad. The second fluids may be different fluids from the first fluids provided by the first delivery arm. The first and second flow rates and first and second temperatures of the first and second fluids, respectively, may be the same or each be different. The second fluid is dispensed to a position on the polishing pad to intersect with a desired portion of the substrate, which is, for example, about 140 mm outward, such as about 150 mm outward from a central axis B of the polishing pad. In some embodiments, the second fluid is dispensed to an outer area of the polishing pad, edge processing region 344, such that the second fluid is delivered to a portion of the substrate via the polishing pad that is at least greater than 50% of the radius of the polishing pad from the central axis B of the polishing pad, such as greater than about 75% of the radius of the polishing pad from the central axis B of the polishing pad, such as greater than about 80% of the radius of the polishing pad from the central axis B of the polishing pad, such as between about 80% and about 95% of the radius of the polishing pad from the central axis B of the polishing pad, such as between about 90% and about 95% of the radius of the polishing pad from the central axis B of the polishing pad. The second fluid is dispensed from one or more nozzles along the second fluid delivery arm and impacts the polishing pad along edge processing region 344, as described above. The second fluid flows along the second fluid path. The beginning of the second fluid path is outward from the beginning of the first fluid path, such that the second fluid path is dispensed outward of the point at which the first fluid is dispensed with respect to the central axis B. The second fluid changes the composition of the first fluid reducing the polishing rate within the edge polishing region.

The mixture of the first and second fluids may change the characteristics of the fluid near the edge of the substrate. The second fluid may be any one of a polishing fluid, chemical solution or water. As described above, the polishing fluid may include a chemical solution and/or a slurry. In some embodiments, a polishing fluid is dispensed from the second fluid delivery arm as the second fluid to increase the amount of polishing fluid near the edge of the substrate. In some embodiments, water is dispensed from the second fluid delivery arm as the second fluid to adjust one or more characteristics of the first fluid provided from the first delivery arm. In some cases, the second fluid, which includes water, is provided to reduce the amount of polishing fluid near the edge of the substrate, control the temperature and/or concentration of the combined first fluid and second fluid, and/or to thin the polishing fluid, which may have built up near the edge of the substrate.

In some embodiments, the substrate carrier assembly and the second fluid delivery arm are both moveable and move during the second operation 404. The substrate carrier assembly moves along the top surface of the polishing pad and moves the substrate to different positions along the polishing pad. The second fluid delivery arm may be controlled to track the movement of the substrate carrier assembly while the substrate carrier assembly moves. The second fluid delivery arm may track the substrate carrier assembly by moving with the substrate carrier assembly.

In some embodiments, the second fluid delivery arm is configured to move so that a radial location at which fluids dispensed from the second fluid delivery arm intersect the substrate carrier assembly at the same location, such that dispensed fluid intersects the substrate at the same radial position on the substrate as the substrate carrier assembly moves. In this embodiment, the second fluid delivery arm would always deliver the second fluid to a similar radius of the substrate carrier assembly from the center of the substrate carrier assembly. This tracking may include the swinging of the second fluid delivery arm about the axis E to either extend further over the polishing pad or reduce the amount of extension over the polishing pad.

In some embodiments, the second fluid delivery arm is configured to move so that the fluid path caused by the delivery of fluid from the second fluid delivery arm intersects the substrate carrier assembly at the same relative position on the substrate carrier assembly at all times. In this embodiment, the rotation of the second fluid delivery arm about the axis E is controlled so that the end of the fluid path of the fluid from the second fluid delivery arm consistently intersects the substrate carrier assembly at a similar radial and angular position relative to the carrier axis A.

The type of second fluid dispensed by the first delivery arm and second fluid delivery arm is dependent upon the material being polished from the substrate. In embodiments in which oxides are being polished by the polishing system, the temperature of the second fluid may be controlled by a temperature control unit, such as the temperature control unit 304.

The second operation 404 may include simultaneous dispensing of the first fluid or the dispensing of the first fluid may be halted during the second operation 404. Even if the dispensing of the first fluid is halted, the rotation of the polishing pad and the substrate carrier assembly is maintained. In some embodiments, the rotational velocity of the polishing pad and/or the substrate carrier assembly is decreased or increased during the second operation, but the rotation will continue without halting of the polishing pad or the substrate carrier assembly.

A metrology unit, such as the metrology unit 165, may measure the thickness of the substrate to estimate the rate of removal caused by polishing. The metrology unit is connected to a controller and the controller can determine an appropriate amount of second fluid and the temperature of the second fluid to be utilized if any second fluid is used, such that the controller determines a dispensing rate from the second fluid delivery arm based upon the measured thickness of the substrate. In some embodiments, the temperature of the second fluid is increased to increase the polishing rate at the edge of the substrate. In other embodiments, the temperature of the second fluid is decreased to decrease the polishing rate at the edge of the substrate. The metrology unit may be an inductive metrology unit (e.g. eddy current) or a spectral metrology unit (e.g., optical metrology).

In some operations, the metrology unit is not utilized and the second fluid is instead dispensed on a timed sequence, such that the second fluid is dispensed at set intervals during the polishing process. In some embodiments, the second fluid is dispensed continuously, but the flow rate and/or temperature of the second fluid is adjusted over time.

The third operation 406 includes stopping the substrate polishing and the dispensing of the first fluid and second fluid. The third operation 406 is performed after each of the first and second operations 402, 404 have been completed. The substrate polishing and the dispensing of the first fluid and second fluid are stopped once the polishing operation being performed on the substrate has been completed. As discussed above, in some embodiments, the second fluid deliver arm 138 removed a fluid from the pad surface by use of a vacuum and/or delivers a fluid to the polishing pad to control the composition of the polishing fluid to control the polishing rate at the edge of the substrate.

In some embodiments, the third operation includes the delivery of a cleaning chemistry, such as for example PlanarClean® and/or PL6502, for a desired period of time to remove the abrasive particles embedded within, bonded to or residing on the surface of the polishing pad within the edge region. In some embodiments, the third operation may include the delivery of megasonic energy to a fluid or the cleaning chemistry to remove the abrasive particles embedded within, bonded to or residing on the surface of the polishing pad.

Embodiments disclosed herein relate to a second fluid delivery arm configured to deliver a second fluid to a polishing pad within a CMP system. The second fluid delivery arm is different from the first fluid delivery arm in that the second fluid delivery arm is configured to dispense fluid to the edges of the substrate while having significantly reduced impact on the amount of polishing fluid near the center of the substrate. In some embodiments, the fluid delivered by the second fluid delivery arm would only significantly impact the polishing rate of the outer 10 mm of the substrate, such that for a 300 mm diameter substrate, the polishing rate at the outermost 10 mm of the substrate would be impacted, but the inner 140 mm would have substantially unchanged polishing rates.

The processes used within the disclosure above may vary depending upon the type of polishing process. Some polishing processes may utilized the temperature control unit and the metrology unit, while other processes may not utilize the temperature control unit or the metrology unit. Similarly, some polishing processes utilize an automated dispense process based upon previous experimental results and do not utilize a metrology unit. If the polishing processes described herein are related to an oxide polishing process, the temperature control unit and the metrology unit may be utilized. If the polishing processes described herein are related to a metal polishing process, the process may be automated and the controller may dispense the second fluid at pre-determined intervals without the use of a metrology unit. While as described above the temperature control unit and the metrology unit is primarily utilized during oxide polishing processes, it is contemplated the temperature control unit and the metrology unit may also be utilized with metal processes, such as a tungsten polishing process.

While the foregoing is directed to embodiments of the present disclosure, other and further embodiments of the disclosure may be devised without departing from the basic scope thereof, and the scope thereof is determined by the claims that follow.

What is claimed is:

1. An apparatus for processing a substrate, comprising:
a pad disposed on a platen, wherein the pad has a pad radius and a central axis from which the pad radius extends;
a carrier assembly configured to be disposed on a surface of the pad and having a carrier radius that extends from a rotational axis of the carrier assembly, wherein the rotational axis is disposed at a first radial distance from the central axis;
a first fluid delivery arm having a first nozzle configured to provide a first fluid to a first point on a surface of the pad at a second radial distance from the central axis; and
a second nozzle configured to provide a second fluid to a second point on the surface of the pad, the second point disposed a third radial distance from the central axis, wherein the third radial distance is greater than or equal to the first radial distance and the second radial distance.

2. The apparatus of claim 1, wherein the second nozzle is positioned on a second fluid delivery arm that is positionable over a portion of the surface of the pad.

3. The apparatus of claim 1, wherein the second nozzle is positioned on the first fluid delivery arm.

4. An apparatus for processing a substrate, comprising:
a platen;
a pad disposed on the platen, the pad having a pad radius extending from a central axis;
a carrier assembly disposed on the pad having a carrier radius that extends from a rotational axis of the carrier assembly;
a first fluid delivery arm configured to provide a first fluid to a first point on the pad; and
a second fluid delivery arm configured to provide a second fluid to a second point on the pad, the second point disposed a radial distance from the central axis, the radial distance being greater than about 75% of the pad radius.

5. A method of polishing a substrate comprising:
urging a substrate against a surface of a pad of a polishing system using a carrier assembly, wherein the pad has a pad radius and a central axis from which the pad radius extends;
translating the carrier assembly across a surface of the pad while rotating the carrier assembly about a rotational axis;
dispensing a first fluid onto the pad from a first fluid nozzle at a first flow rate, wherein the first fluid is delivered to the pad at a second radial distance that is measured from the central axis; and
dispensing a second fluid onto the pad from a second fluid nozzle at a second flow rate, wherein the second fluid is delivered to the pad at a third radial distance that is measured from the central axis, such that the third radial distance is greater than the second radial distance.

6. The method of claim 5, wherein the first fluid and the second fluid are different.

7. The method of claim 5, wherein the first fluid flow rate and the second fluid flow rate are different.

8. The method of claim 5, wherein the first fluid is at a first temperature and the second fluid is at a second temperature, and the temperatures are controlled by a temperature control unit to adjust a polishing rate.

9. The method of claim 8, wherein the first fluid temperature and the second fluid temperature are different.

10. The method of claim 5, wherein the second fluid is dispensed onto the pad at a radial position outward from an innermost edge of the carrier assembly with respect to the central axis of the pad, but inward from an outermost edge of the carrier assembly with respect to the central axis of the pad.

11. The method of claim 5, wherein the carrier assembly and the second fluid nozzle are both moveable and track one another so the fluid dispensed from the second fluid delivery nozzle intersects a same portion of the carrier assembly as the carrier assembly is translated across the surface of the pad.

12. The method of claim 5, wherein the pad has a polishing control groove, the polishing control groove has a depth of between about 10 mils to about 80 mils and a width of between about 3 to 50 millimeters.

13. The method of claim 12, wherein the polishing the polishing control groove is positioned near the outer edge of the pad.

14. The method of claim 13, wherein the polishing control groove is positioned within 15% of the outer edge of the pad by radius.

15. The method of claim 5, further comprising a vacuum pressure provided from a vacuum nozzle and the vacuum nozzles is positioned between about 1 and 5 mm above the top surface of the substrate.

16. The method of claim 15, wherein providing a vacuum pressure along the edge of the substrate removes fluid from the edge of the substrate.

17. The method of claim 12, further comprising providing a vacuum pressure along the edge of the substrate removing fluid from the polishing control groove.

18. The method of claim 5, wherein the second fluid is provided through a plurality of nozzles having at least a first and a second nozzle.

19. The method of claim 18, wherein the plurality of nozzles are angled to project the second fluid at an angle with regards to the top surface of the pad that is not perpendicular to the pad.

20. The method of claim 19, wherein the plurality of nozzles are further angled to project the second fluid toward the pad edge and avoid spraying the second fluid towards the center of the pad.
